(19) United States
(12) Patent Application Publication
(10) Pub. No.: US 2014/0176233 A1
(43) Pub. Date: Jun. 26, 2014

(54) Bandwidth Calibration for Filters

(71) Applicant: Hong Kong Applied Science and Technology Research Institute Company Limited, (US)

(72) Inventors: Xiaoming Chen, Shenzhen (CN); Shuzuo Lou, Hong Kong (HK); Gang Qian, Hong Kong (HK); Wai Po Wong, Hong Kong (HK)

(73) Assignee: Hong Kong Applied Science and Technology Research Institute Company Limited, Hong Kong (HK)

(21) Appl. No.: 13/721,018

(22) Filed: Dec. 20, 2012

(51) Int. Cl. H03H 21/00

(52) U.S. Cl. CPC H03H 21/0007
USPC 327/554

(57) ABSTRACT

A low power, high accuracy calibration circuit for filter calibration is provided. The calibration circuit includes a chargeable voltage storage element. A first measurement and adjustment circuit determines a charge time required for the voltage of the chargeable voltage storage element to substantially match a reference voltage. The circuit adjusts the voltage storage element to make the charge time approximately equal to a predetermined filter time constant value, the adjustment circuit updating the reference voltage to make the charge time substantially equal to the predetermined filter time constant value and iteratively updating the reference voltage to refine the charge time. A second circuit is configured to have substantially the predetermined filter time constant value based on the adjustment configuration determined by the adjustment of the voltage storage element and the reference voltage of the first circuit.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The invention relates to calibration circuits in general and, more particularly, to calibration circuits for filters such as analogue filters for signal processing.

### BACKGROUND

Analog filters are widely used in signal processing to pass desired signals and reject unwanted interference. However, analog filter operational bandwidth can vary from design specifications by ±30% due to various factors in filter processing, voltage, and operating temperature (“PVT”). Therefore, automatic bandwidth calibration is required to compensate for PVT variations in filters. Although various approaches have been made to calibrate filter bandwidth, conventional approaches typically consume large chip areas, require high supply voltages, and are easily degraded by noise, negatively impacting the bandwidth calibration. Further, high resolution bandwidth calibration often requires long calibration times. Thus there is a need in the art for improved calibration techniques, particularly calibration techniques consuming low power and small amounts of chip real estate.

### SUMMARY OF THE INVENTION

It is an objective of the presently claimed invention to provide a low power, high accuracy calibration circuit for filter calibration. The calibration circuit includes a chargeable voltage storage element. A first measurement and adjustment circuit determines a charge time required for the voltage of the chargeable voltage storage element to substantially match a reference voltage. The circuit adjusts the voltage storage element to make the charge time approximately equal to a predetermined filter time constant value, the adjustment circuit updating the reference voltage to make the charge time substantially equal to the predetermined filter time constant value and iteratively updating the reference voltage to refine the charge time. A second circuit is configured to have substantially the predetermined filter time constant value based on the adjustment configuration determined by the adjustment of the voltage storage element and the reference voltage of the first circuit.

### BRIEF DESCRIPTION OF THE DRAWINGS

Embodiments of the invention are described in more detail hereinafter with reference to the drawings, in which

FIG. 1 is a schematic depiction of an underlying principle of filter calibration;

FIG. 2 is a schematic depiction of calibration according to one embodiment of the present invention;

FIG. 3A is a schematic depiction of a DAC implementation according to an embodiment of the present invention while FIG. 3B is a digital logic diagram corresponding to FIG. 3A;

FIG. 4A is an overview of the initialization of the calibration process while FIG. 4B is a flow chart of setting and updating V₀ and V′_{ref}; and

FIG. 5 is a schematic depiction of the calibration module implementation according to one embodiment of the present invention and an exemplary embodiment of a filter.

### DETAILED DESCRIPTION

In the following description, circuits for analog filter bandwidth calibration and the like are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

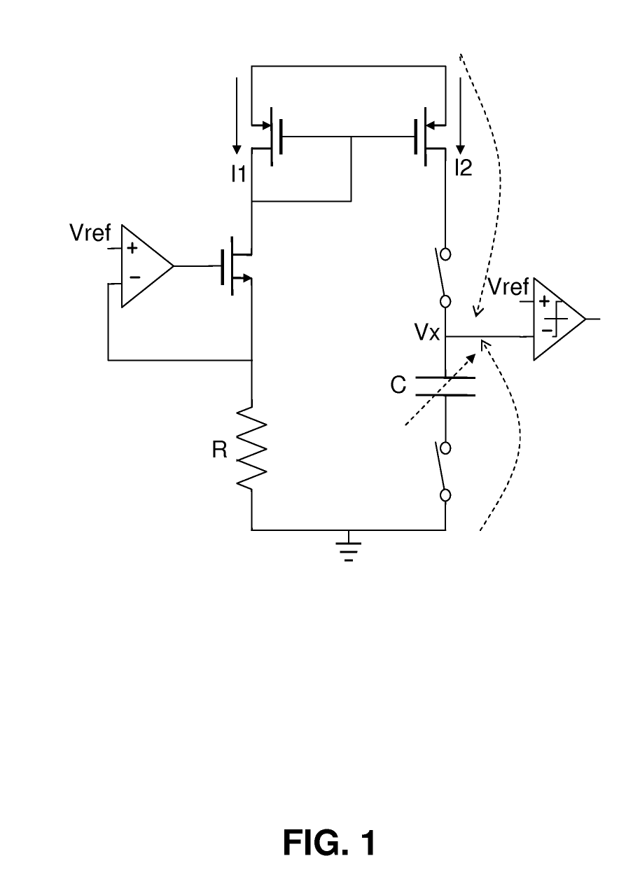

In general, filter bandwidth is inversely proportional to the product of the resistance and capacitance, known at the RC time constant. To calibrate a filter, the RC time constant is measured to determine the variation from the design specification. Once the variation is known, the RC time constant can be altered to approximate the design specification, compensating for PVT variations. Turning to FIG. 1, an approach to filter calibration is depicted. In the circuit, Vx is charged by I2 until it reaches the reference voltage V_{ref} required to make comparator flip. By varying the capacitance, C, of the variable capacitor, the charging time (RC time constant) is controlled to be equal to a value T, where T is set by a precise crystal clock that is insensitive to PVT variations.

However, for high resolution calibration, more control bits are required. This requires a large array of capacitors. This large capacitor array in the calibration circuit occupies a large chip area and consumes a large charging current. Further, noise from the power supply and ground affects comparator decision. Also, a mismatch in I1 and I2 can cause systemic error.

However, the novel approach of the present invention reduces the calibration capacitance, its associated chip area, and charging current by a reference adaptation scheme without sacrificing calibration accuracy. The approach of the present invention also improves immunity to noise from the supply and ground by performing multiple comparisons and then averaging. Further, current matching is improved through the use of a cascode current mirror.

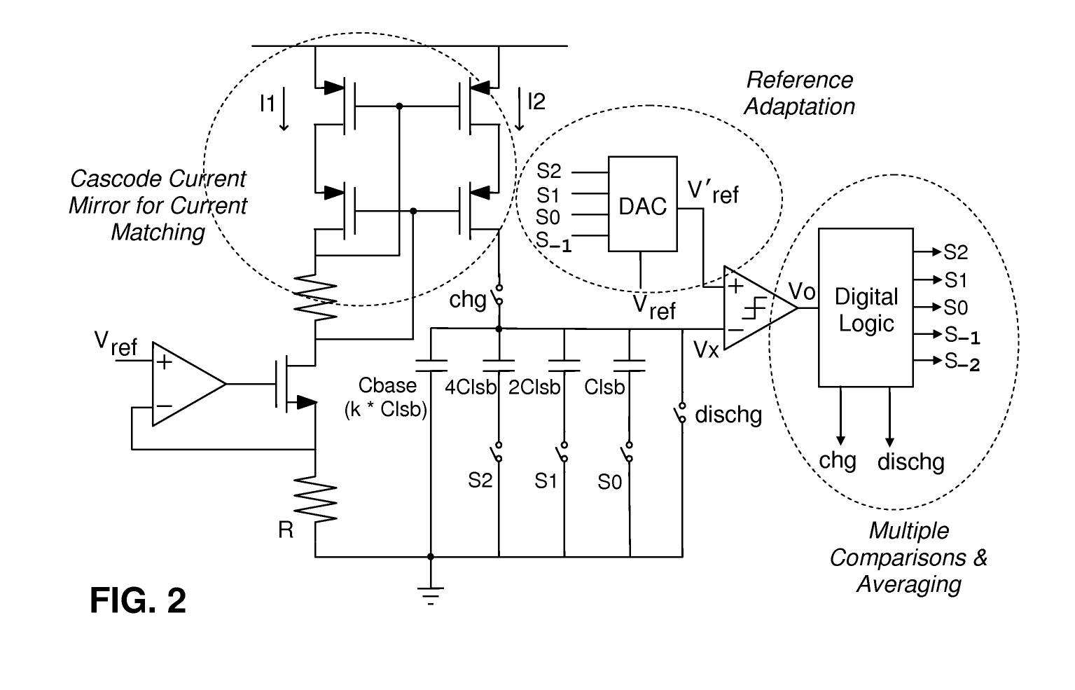

As seen in the exemplary embodiment of the present invention schematically depicted in FIG. 2, the reference adaptation scheme is performed in portion 200, the multiple comparisons and averaging are provided in digital logic portion 300, while current matching is performed in cascade mirror portion 100.

To provide rapid and accurate calibration in the present invention, the calibration is divided into coarse and fine phases. To get m+n bits calibration accuracy, only m bits MSBs (Most-Significant-Bits) are settled in capacitor array. Advantageously, this reduces the size of the capacity array, saving valuable chip space and reducing power consumption. The remaining n LSBs (Least-Significant-Bits) are resolved in the inventive reference adaptation scheme. In determining −n^{th} bit, V′_{ref} is set to:

$${V}_{ref , - n}^{′} = {V}_{ref} ( 1 + \frac{{\sum }_{a = 1}^{n - 1} ( {{S}_{- a} ( 1 \text{/} 2 )}^{a} ) + {( 1 \text{/} 2 )}^{n}}{k + {\sum }_{b = 0}^{m - 1} {S}_{b} \cdot {2}^{b}} )$$

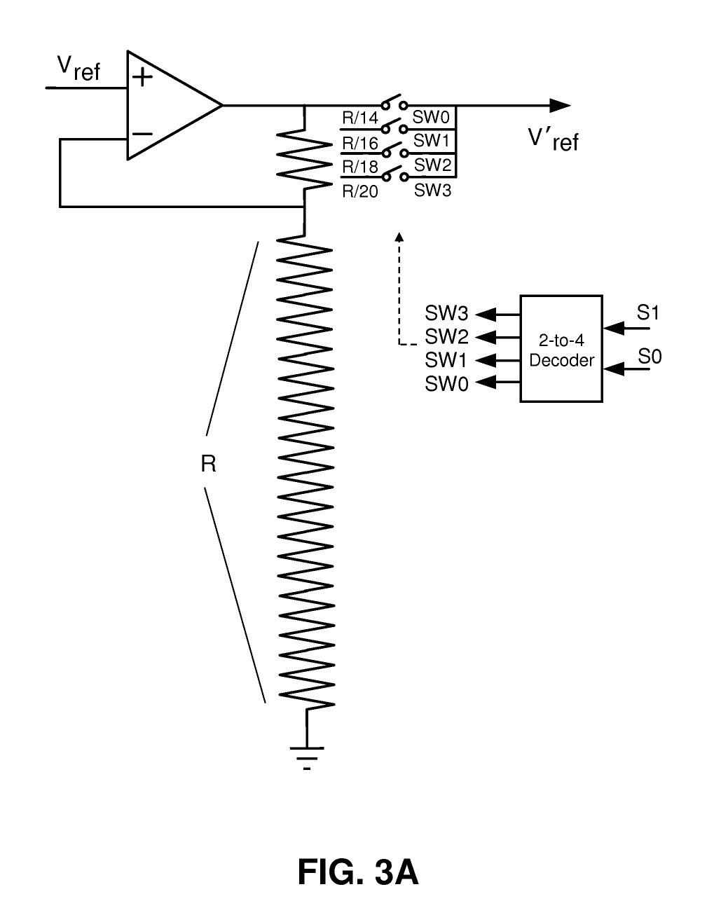

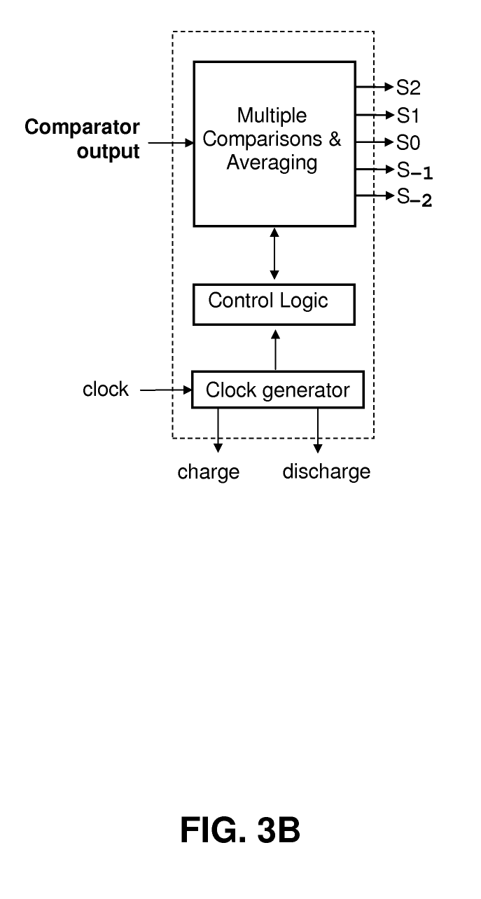

To perform this, an m+n−1 bits DAC (Digital-to-Analog Converter) is used for V′_{ref} adaptation. A schematic depiction of the DAC implementation is shown in FIG. 3A and the corresponding digital logic diagram is shown in FIG. 3B. The digital logic minimizes the comparator error by performing multiple comparisons and averaging of the results. Therefore the accuracy of bandwidth calibration is improved.

For example, capacitor voltage (Vx) is easily affected by noise from power and ground. Thus for a single measurement at a period of high noise, the comparator will probably output wrong result. Therefore, the digital logic controls the comparator to compare M times between capacitor voltage and reference voltage. (M is decided by the maximum time allowed for the bandwidth calibration.) If a logic high from comparator output is obtained N times, the bandwidth calibration control code is considered to be correct (50%*M<N<M). As a result, one or more comparison errors will not cause an incorrect bandwidth calibration code. The values of M and N values are set to adjust for a predetermined level of error tolerance.

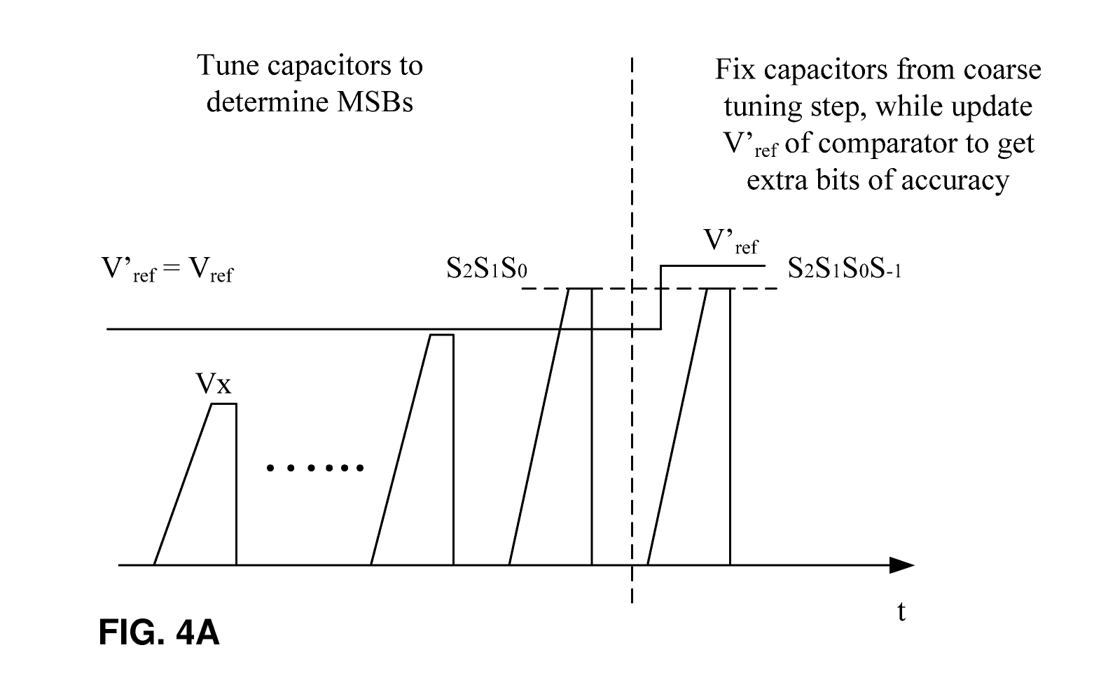

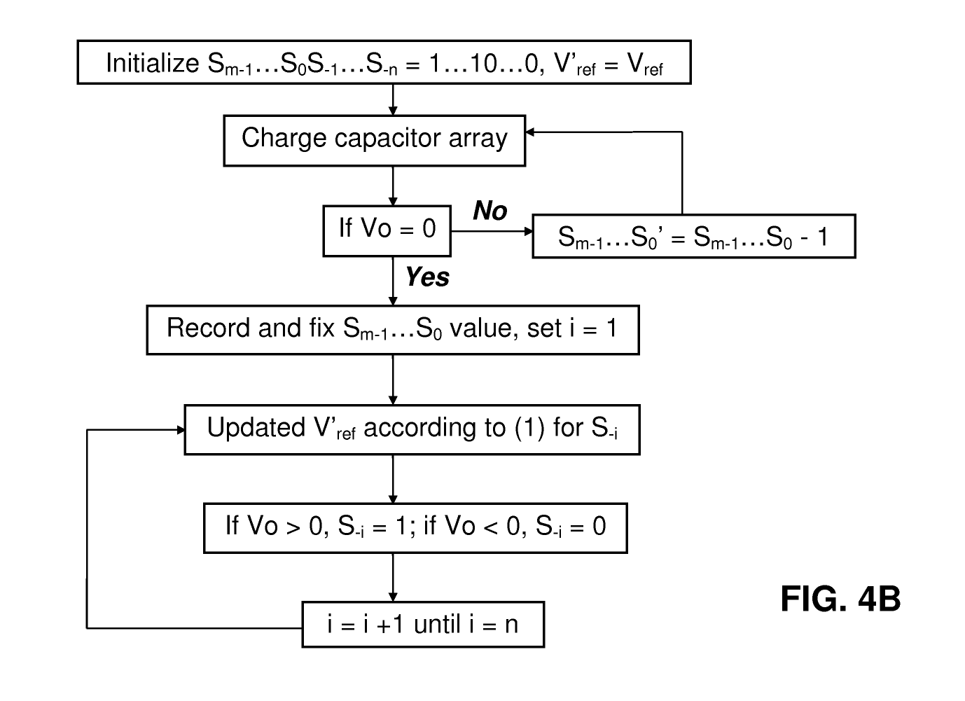

In more detail, referring to FIG. 4A and FIG. 4B, calibration is performed as follows: Linearly search variable capacitors, decreasing from S₂S₁S₀=111, V′_{ref} is set to V_{ref}. When the comparator output V₀ changes from “1” to “0”, then record the S₂S₁S₀ value.

Next, update V′_{ref}:

$${V}_{ref}^{′} = {V}_{ref} ( 1 + \frac{1 \text{/} 2}{k + 4 * {S}_{2} + 2 * {S}_{1} + 1 * {S}_{0}} )$$

If Vx>V′_{ref}, S₋₁=“1”, otherwise, S₋₁=“0”.

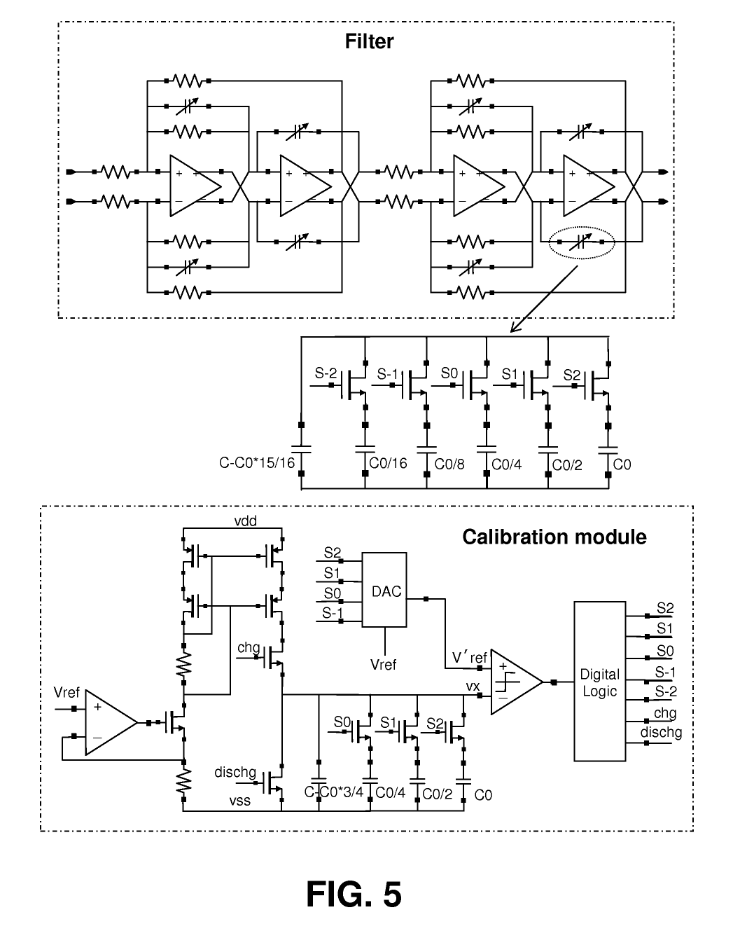

FIG. 5. shows a circuit diagram of a calibration module implemented according to one embodiment of the present invention, along with an exemplary filter with signals S−2, S−1, S0, S1, and S2 from the calibration module feeding to it.

The foregoing description of the present invention has been provided for the purposes of illustration and description. It is not intended to be exhaustive or to limit the invention to the precise forms disclosed. Many modifications and variations will be apparent to the practitioner skilled in the art.

While the invention has been described with respect to various exemplary features and advantages, it will be appreciated that the present invention is not limited to such features and that numerous other variations, alternatives, and modifications can be made without departed from the scope and spirit of the appended claims.

What is claimed is:

1. A low power, high accuracy calibration circuit for calibrating an analogue filter, the calibration circuit comprising:
a chargeable voltage storage element;
a first measurement and adjustment circuit for determining a charge time required for a voltage of the chargeable voltage storage element to substantially match a reference voltage and for adjusting the chargeable voltage storage element to make the charge time approximately equal to a predetermined filter time constant value, the adjustment circuit updating the reference voltage to make the charge time substantially equal to the predetermined filter time constant value and iteratively updating the reference voltage to refine the charge time;
a second circuit configured to have substantially the predetermined filter time constant value based on an adjustment configuration determined by the adjustment of the chargeable voltage storage element and the reference voltage.

2. The low power, high accuracy calibration circuit according to claim 1 wherein the second circuit includes a capacitor array, and the adjustment configuration is configured to control the second circuit capacitor array.

3. The low power, high accuracy calibration circuit according to claim 1 wherein the second circuit further comprises a resistor array and the adjustment configuration is applied to both the capacitor array and the resistor array of the second circuit.

4. The low power, high accuracy calibration circuit according to claim 2 wherein the capacitor array is a switchable capacitor array configured to be switchable to a selected filter cut-off frequency.

5. The low power, high accuracy calibration circuit according to claim 1 further comprising a digital-to-analogue converter including a resistor ladder and switches controlled by digital input bits, the digital-to-analogue converter configured to iteratively update the reference voltage.

6. The low power, high accuracy calibration circuit according to claim 1 wherein the first measurement and adjustment circuit further comprises a comparator and wherein the charge time is determined by a time required for the comparator to flip.

7. The low power, high accuracy calibration circuit according to claim 6 further comprising one or more digital logic circuits configured to make decisions based upon multiple comparisons from the comparator.

8. The low power, high accuracy calibration circuit according to claim 1 further comprising a low-voltage cascade current mirror for providing charging current for the chargeable voltage storage element.

9. A method for calibrating an analogue filter with high calibration accuracy using a low power, comprising:
charging a chargeable voltage storage element;
determining a charge time required for a voltage of the chargeable voltage storage element to substantially match a reference voltage;
adjusting the chargeable voltage storage element to make the charge time approximately equal to a predetermined filter time constant value;
updating the reference voltage to make the charge time substantially equal to the predetermined filter time constant value based an adjustment configuration determined by the adjustment of the chargeable voltage storage element;
iteratively updating the reference voltage to refine the charge time; and
configuring a second circuit to have substantially the predetermined filter time constant value based on an adjustment configuration determined by the adjustment of the chargeable voltage storage element and the reference voltage.

10. The method according to claim 9, wherein the second circuit includes a capacitor array, and the adjustment configuration is configured to control the second circuit capacitor array.

11. The method according to claim 9, wherein the second circuit further comprises a resistor array and the adjustment configuration is applied to both the capacitor array and the resistor array of the second circuit.

12. The method according to claim 10, wherein the capacitor array is a switchable capacitor array configured to be switchable to a selected filter cut-off frequency.

13. The method according to claim 9, further comprising iteratively updating the reference voltage using a digital-to-analogue converter comprising a resistor ladder and switches controlled by digital input bits.

14. The method according to claim 9, wherein the first measurement and adjustment circuit further comprises a comparator and wherein the charge time is determined by a time required for the comparator to flip.

15. The method according to claim 14, further comprising making decisions based upon multiple comparisons from the comparator using one or more digital logic circuits.

16. The method according to claim 9, further comprising providing a charging current for the chargeable voltage storage element using a low-voltage cascade current mirror.
